(19) United States
(12) Patent Application Publication
(10) Pub. No.: US 2023/0023235 A1
(43) Pub. Date: Jan. 26, 2023

(54) ENHANCED STRESS TUNING AND INTERFACIAL ADHESION FOR TUNGSTEN (W) GAP FILL

(71) Applicant: Applied Materials, Inc., Santa Clara, CA (US)

(72) Inventors: Xi CEN, San Jose, CA (US); Yun TAEWOONG, Pleasanton, CA (US); Shirish A. PETHE, Cupertino, CA (US); Kai WU, Palo Alto, CA (US); Nobuyuki SASAKI, Cupertino, CA (US); Wei LEI, Campbell, CA (US)

(21) Appl. No.: 17/477,413

(22) Filed: Sep. 16, 2021

Related U.S. Application Data
(60) Provisional application No. 63/225,623, filed on Jul. 26, 2021.

(51) Int. Cl. H01L 21/768

(52) U.S. Cl. CPC H01L 21/76876; H01L 21/76879; H01L 21/7684

(57) ABSTRACT

Embodiments of methods and associated apparatus for filling a feature in a substrate are provided herein. In some embodiments, a method of filling a feature in a substrate includes: depositing a seed layer of tungsten nitride in the feature via a physical vapor deposition (PVD) process; depositing a liner layer of tungsten on the seed layer of tungsten nitride in the feature via a PVD process; and subsequently filling the feature with a tungsten bulk fill via a chemical vapor deposition (CVD) process.

### CROSS-REFERENCE TO RELATED APPLICATIONS

This application claims benefit of U.S. provisional patent application Ser. No. 63/225,623, filed Jul. 26, 2021, which is incorporated herein by reference in its entirety.

### FIELD

Embodiments of the present disclosure generally relate to processing of substrates, such as semiconductor substrates.

### BACKGROUND

Integrated circuits are formed by processes that produce intricately patterned material layers on substrate surfaces. Tungsten is used in the semiconductor industry as a lower resistivity conductor with minimal electro-migration. Tungsten may be used to fill holes as contacts for transistors and in the formation of vias between layers of integrated devices. Tungsten may also be used for interconnects in logic and memory devices due to tungsten's stability and low resistivity. As technology progresses, a demand is created for even lower resistivity and lower stress metal fill solutions. However current tungsten fill processes that offer lower resistivity and lower stress offer insufficient adhesion for planarization processes. Current tungsten fill processes also do not offer adequate control over tuning stress of the tungsten fill.

Accordingly, the inventors have provided improved processes for tungsten fill.

### SUMMARY

Embodiments of methods and associated apparatus for filling a feature in a substrate are provided herein. In some embodiments, a method of filling a feature in a substrate includes: depositing a seed layer of tungsten nitride in the feature via a physical vapor deposition (PVD) process; depositing a liner layer of tungsten on the seed layer of tungsten nitride in the feature via a PVD process; and subsequently filling the feature with a tungsten bulk fill via a chemical vapor deposition (CVD) process.

In some embodiments, a method of filling a feature in a substrate includes depositing a seed layer of tungsten nitride in the feature via a physical vapor deposition (PVD) process; depositing a liner layer of tungsten on the seed layer of tungsten nitride in the feature via a PVD process; performing a nitrogen radical treatment on the liner layer to provide an incubation delay for a subsequent deposition process; and subsequently filling the feature with a tungsten bulk fill via a chemical vapor deposition (CVD) process.

In some embodiments, a computer readable medium comprising one or more processors, that when executed, perform a method of filling a feature in a substrate includes: depositing a seed layer of tungsten nitride in the feature via a physical vapor deposition (PVD) process; depositing a liner layer of tungsten on the seed layer of tungsten nitride in the feature via a PVD process; and subsequently filling the feature with a tungsten bulk fill via a chemical vapor deposition (CVD) process.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of filling a feature in a substrate in accordance with at least some embodiments of the present disclosure.

FIG. 2A depicts a cross-sectional view of a high aspect ratio structure after a seed layer is deposited via a physical vapor deposition (PVD) process in accordance with at least some embodiments of the present disclosure.

FIG. 2B depicts a cross-sectional view of a high aspect ratio structure after a liner layer is deposited via a PVD process on a seed layer in accordance with at least some embodiments of the present disclosure.

FIG. 2C depicts a cross-sectional view of a high aspect ratio structure after depositing a bulk fill on a liner layer via a chemical vapor deposition (CVD) process in accordance with at least some embodiments of the present disclosure.

FIG. 3A depicts a cross-sectional view of a high aspect ratio structure after a seed layer is deposited via a physical vapor deposition (PVD) process in accordance with at least some embodiments of the present disclosure.

FIG. 3B depicts a cross-sectional view of a high aspect ratio structure after a liner layer is deposited via a PVD process on a seed layer in accordance with at least some embodiments of the present disclosure.

FIG. 3C depicts a cross-sectional view of a high aspect ratio structure after a nucleation layer is deposited on the liner layer via an atomic layer deposition (ALD) process in accordance with at least some embodiments of the present disclosure.

FIG. 3D depicts a cross-sectional view of a high aspect ratio structure after a bulk fill is deposited on the nucleation layer via a CVD process in accordance with at least some embodiments of the present disclosure.

FIG. 4 depicts a multi-chamber processing tool suitable to perform methods for processing a substrate in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus described herein provide a low resistivity and low stress tungsten gap fill with enhanced interfacial adhesion. The embodiments provided herein may be used to fill structures such as vias, trenches, or the like. The critical dimensions (CD) of the trenches or vias may be within a range of approximately 5 nm to approximately 1000 nm with an aspect ratio (AR) of the features between about 1:1 and about 15:1.

Tungsten is widely used as metallic interconnect in logic and memory devices, because of tungsten's unique stability and low resistivity. However, along with technological advances comes an increasing a need for an even lower resistivity and lower stress metal fill solution with a reasonable gap fill that can meet, for example, requirements for NAND flash memory structures and similar. Conventional CVD tungsten approaches (TiN+CVD tungsten) have high tensile stress. The inventors have found that the stress of CVD tungsten can be lowered by changing deposition conditions but with a large impact on throughput and gap fill performance. The inventors also found that the resistivity of CVD tungsten can be lowered by changing deposition conditions (temperature, tungsten atomic layer deposition (ALD) nucleation chemistry, etc.), but with a limited resistivity response and decreased performance (mainly throughput).

The inventors subsequently discovered an integrated approach that allows for control of tensile stress and lower resistivity of tungsten films with high throughput and improved adhesion. For example, compared to conventional CVD tungsten approaches (TiN+CVD tungsten), the integrated approach maintains similar throughput while reducing resistivity of CVD tungsten by more than 60 percent. The integrated approach generally comprises depositing via PVD, a seed layer of tungsten nitride (WN) prior to a liner layer of tungsten deposited via PVD. The seed layer advantageously adheres to the substrate better than direct deposition of the liner layer of tungsten on to the substrate. The seed layer also promotes the adhesion of the liner layer and subsequent layers to the substrate. The enhanced adhesion reduces or prevents separation of the gap fill, or unplug issues, during subsequent processes. For example, during a planarization process, such as a chemical mechanical planarization (CMP) process. The inventors have also observed that even with the seed layer of WN, lower resistivity is maintained. The inventors have also observed that the tensile stress of the gap fill may advantageously be tuned to a desired stress value by controlling the concentration of nitrogen with respect to tungsten in the seed layer.

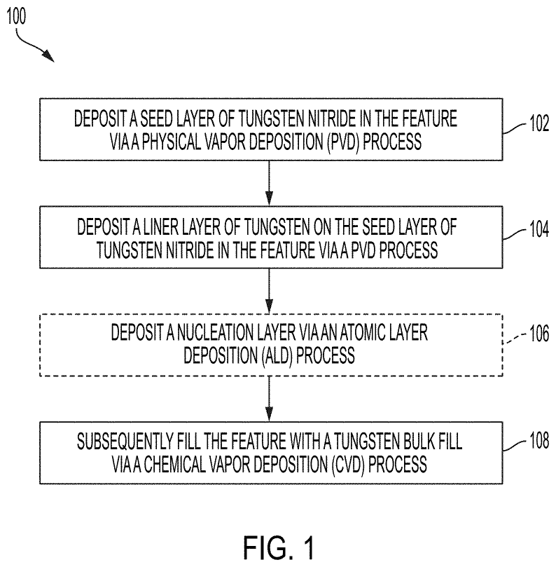

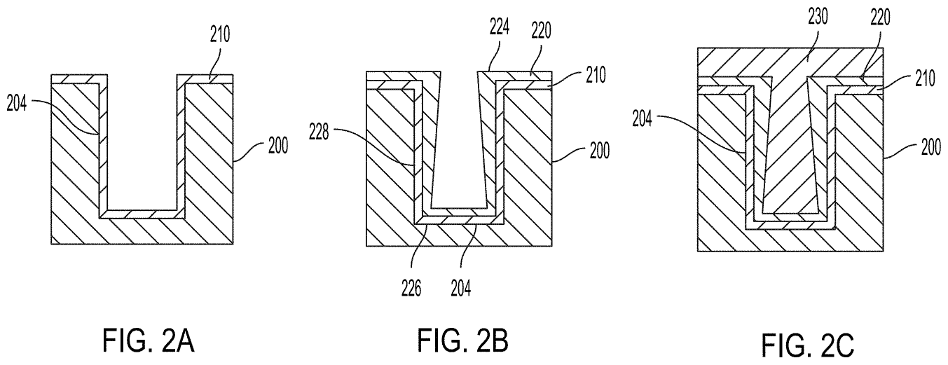

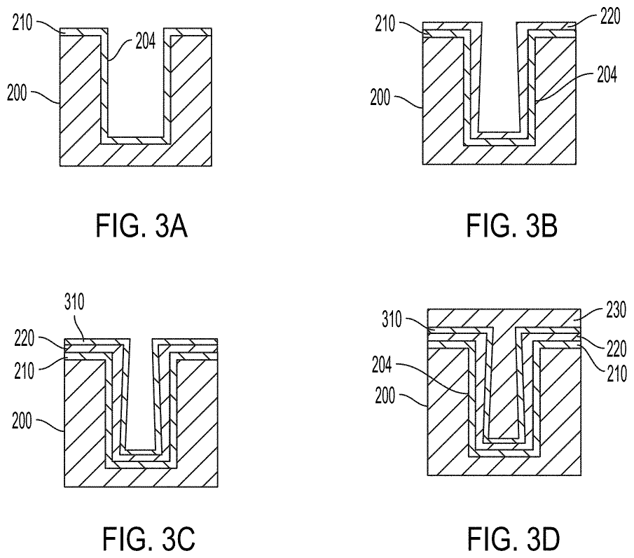

FIG. 1 depicts a flow chart of a method 100 of filling a feature in a substrate in accordance with at least some embodiments of the present disclosure. At 102, the method 100 includes depositing a seed layer 210 of tungsten nitride in a feature 204 of a substrate 200 via a physical vapor deposition (PVD) process, as shown in FIGS. 2A and 3A. The substrate 200 may be made of a dielectric material or consist essentially of silicon oxide. The PVD process is conducted with a high ionization process with an ambient noble gas such as argon, krypton, or the like. A temperature during the seed layer deposition process may be from approximately room temperature (˜20 degrees Celsius) to approximately 350 degrees Celsius. While FIGS. 2A-3D depict the substrate 200 having one feature 204, the substrate 200 may include a plurality of features 204. In some embodiments, a width of each of the features 204 is between about 5 and about 65 nanometers.

The seed layer 210 will have reasonable step coverage on the substrate 200. In some embodiments, the seed layer 210 of tungsten nitride is about 10 to about 60 angstroms thick. The thickness of the seed layer 210 is advantageously chosen to provide enhanced adhesion while minimizing increase in resistivity. A concentration of nitrogen in the seed layer 210 may be tuned to provide a desired stress level, considering the CD of the feature 204, subsequent layers deposited onto the seed layer 210, and the types of processing the substrate 200 will undergo after deposition of the seed layer 210. In some embodiments, the seed layer 210 has a nitrogen concentration of about 3 to about 45 atomic percent. In some embodiments, the seed layer 210 has a nitrogen concentration of about 18 to about 35 atomic percent.

At 104, the method 100 includes depositing a liner layer 220 of tungsten on the seed layer 210 of tungsten nitride in the feature 204 via a PVD process, as shown in FIGS. 2B and 3B. In some embodiments, the PVD process is conducted with a high ionization process with an ambient noble gas such as argon, krypton, or the like. In some embodiments, the liner layer 220 is about 30 to about 300 angstroms thick. In some embodiments, the liner layer 220 is deposited at a temperature of about 20 to about 350 degrees Celsius. In some embodiments, the liner layer 220 is thicker than the seed layer 210.

At 106, the method 100 optionally includes depositing a nucleation layer 310 via an atomic layer deposition (ALD) process after depositing the liner layer 220 of tungsten, as shown in FIG. 3C. In some embodiments, the nucleation layer 310 is deposited using a mixture of tungsten hexafluoride (WF₆) with silane (SiH4) or diborane (B₂H₆) via an atomic layer deposition (ALD) process after depositing the liner layer of tungsten. The nucleation layer 310 advantageously reduces void formation for subsequent fill processes. In some embodiments, the nucleation layer is approximately 10 angstroms to approximately 60 angstroms in thickness.

At 108, the method 100 includes subsequently filling the feature with a tungsten bulk fill 230 via a chemical vapor deposition (CVD) process, as shown in FIGS. 2C and 3D. In some embodiments, the tungsten bulk fill 230 is deposited on the liner layer 220. In some embodiments, the tungsten bulk fill 230 is deposited on the nucleation layer 310. In some embodiments, the CVD process is performed using tungsten hexafluoride (WF₆) and hydrogen (H₂) as precursors, filling the feature 204 with boron free tungsten. The CVD process may be performed at a temperature of approximately 300 degrees Celsius to approximately 500 degrees Celsius and with a pressure of approximately 5 Torr to approximately 300 Torr.

In some embodiments, the method 100 includes performing a nitrogen radical treatment before filling the feature 204 with the tungsten bulk fill 230 to provide an incubation delay for the tungsten bulk fill 230. In the nitrogen radical treatment, or nitridation process, nitrogen radicals on or near a top surface 224 of the liner layer 220 causes the subsequent deposition of the tungsten bulk fill 230 to have an incubation delay on or near the top surface 224, but normal growth proximate the bottom 226 and sidewalls 228 of the feature 204. The nitridation process results in a bottom-up or super-conformal deposition behavior of the tungsten bulk fill deposition to reduce void formation inside of the feature 204. In some embodiments, the nitridation process includes flowing nitrogen at a rate of approximately 1 sccm to approximately 20 sccm with a duration of approximately 2 seconds to approximately 20 seconds. A local or remote plasma source may be used.

In some embodiments, the nucleation layer 310 is applied before the nitrogen radical treatment to enhance the incubation delay on the top surface 224. The internal stress level of subsequently deposited tungsten will remain the same, but the resistivity of the subsequently deposited bulk fill tungsten may increase approximately 10% compared to processes without the nucleation layer 310. In some embodiments, a planarization process may be performed on the substrate 200 after filling the feature 204 with the tungsten bulk fill 230.

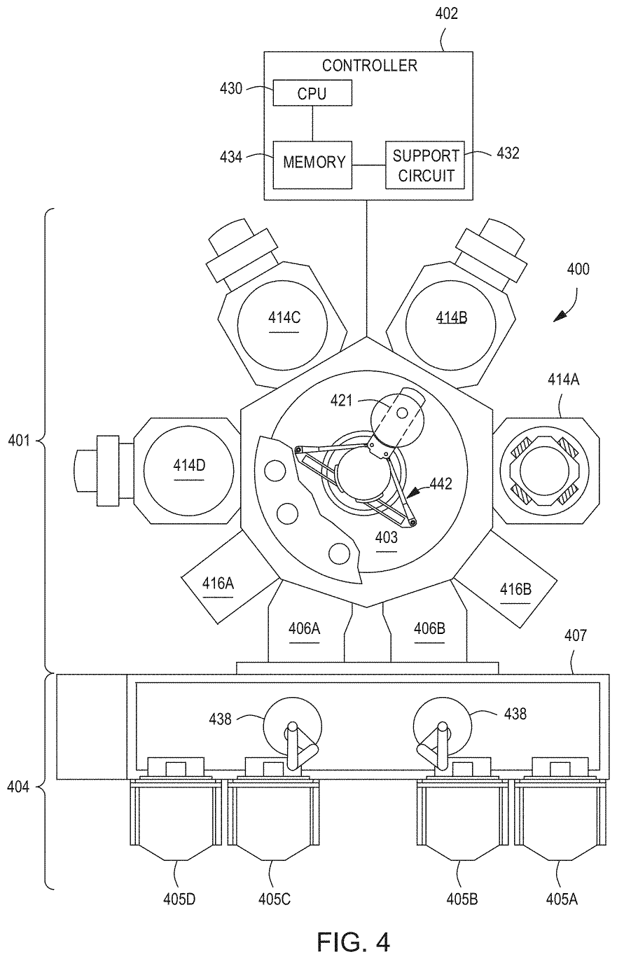

FIG. 4 depicts a multi-chamber processing tool 400 suitable to perform methods for processing a substrate in accordance with some embodiments of the present disclosure. The methods described herein may be practiced using other multi-chamber processing tools having suitable process chambers coupled thereto, or in other suitable process chambers. For example, in some embodiments, the inventive methods discussed above may be advantageously performed in a multi-chamber processing tool such that there are limited or no vacuum breaks between processes. For example, reduced vacuum breaks may limit or prevent contamination of any substrates being processed in the multi-chamber processing tool. Other process chambers, including ones available from other manufacturers, may also be suitably used in connection with the teachings provided herein.

The multi-chamber processing tool 400 includes a processing platform 401 that is vacuum-tight, a factory interface 404, and a system controller 402. The processing platform 401 includes multiple processing chambers, such as 414A, 414B, 414C, and 414D, operatively coupled to a transfer chamber 403 that is under vacuum. The factory interface 404 is operatively coupled to the transfer chamber 103 by one or more load lock chambers, such as 406A and 406B shown in FIG. 4.

In some embodiments, the factory interface 404 comprises at least one docking station 407 and at least one factory interface robot 438 to facilitate the transfer of the substrates. The at least one docking station 407 is configured to accept one or more front opening unified pod (FOUP). Four FOUPS, identified as 405A, 405B, 405C, and 405D, are shown in FIG. 4. The at least one factory interface robot 438 is configured to transfer the substrates from the factory interface 404 to the processing platform 401 through the load lock chambers 406A, 406B. Each of the load lock chambers 406A and 406B have a first port coupled to the factory interface 404 and a second port coupled to the transfer chamber 403. In some embodiments, the load lock chambers 406A and 406B are coupled to one or more service chambers (e.g., service chambers 416A and 416B). The load lock chambers 406A and 406B are coupled to a pressure control system (not shown) which pumps down and vents the load lock chambers 406A and 406B to facilitate passing the substrates between the vacuum environment of the transfer chamber 403 and the substantially ambient (e.g., atmospheric) environment of the factory interface 404.

The transfer chamber 403 has a vacuum robot 442 disposed therein. The vacuum robot 442 is capable of transferring a substrate 421 between the load lock chamber 406A and 406B, the service chambers 416A and 416B, and the processing chambers 414A, 414B, 414C, and 414D. In some embodiments, the vacuum robot 442 includes one or more upper arms that are rotatable about a respective shoulder axis. In some embodiments, the one or more upper arms are coupled to respective forearm and wrist members such that the vacuum robot 442 can extend into and retract from any processing chambers coupled to the transfer chamber 403.

The processing chambers 414A, 414B, 414C, and 414D, are coupled to the transfer chamber 403 and may be configured to perform the methods described herein. Each of the processing chambers 414A, 414B, 414C, and 414D may comprise a chemical vapor deposition (CVD) chamber, an atomic layer deposition (ALD) chamber, a physical vapor deposition (PVD) chamber, a plasma enhanced atomic layer deposition (PEALD) chamber, a preclean/annealing chamber, or the like. For example, processing chamber 414A is a PVD chamber. In some embodiments, processing chamber 414B is CVD process chamber.

Embodiments in accordance with the present disclosure may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

For example, the system controller 402 controls the operation of the multi-chamber processing tool 400 using a direct control of the service chambers 416A and 416B and the process chambers 414A, 414B, 414C, and 414D or alternatively, by controlling the computers (or controllers) associated with the service chambers 416A and 416B and the process chambers 414A, 414B, 414C, and 414D. The system controller 402 generally includes a central processing unit (CPU) 430, a memory 434, and a support circuit 432. The CPU 430 may be one of any form of a general-purpose computer processor that can be used in an industrial setting. The support circuit 432 is conventionally coupled to the CPU 430 and may comprise a cache, clock circuits, input/output subsystems, power supplies, and the like. Software routines, such as processing methods as described above may be stored in the memory 434 and, when executed by the CPU 430, transform the CPU 430 into a system controller 402. The software routines may also be stored and/or executed by a second controller (not shown) that is located remotely from the multi-chamber processing tool 400.

In operation, the system controller 402 enables data collection and feedback from the respective chambers and systems to optimize performance of the multi-chamber processing tool 400 and provides instructions to system components. For example, the memory 434 can be a non-transitory computer readable storage medium having instructions that when executed by the CPU 430 (or system controller 402) perform the methods described herein.

The terms “about” or “approximately” used herein may be within any suitable range, for example, within 15%. While the foregoing is directed to embodiments of the present disclosure, other and further embodiments of the disclosure may be devised without departing from the basic scope thereof.

1. A method of filling a feature in a substrate, comprising:
depositing a seed layer of tungsten nitride in the feature via a physical vapor deposition (PVD) process;
depositing a liner layer of tungsten on the seed layer of tungsten nitride in the feature via a PVD process; and
subsequently filling the feature with a tungsten bulk fill via a chemical vapor deposition (CVD) process.

2. The method of claim 1, wherein the seed layer of tungsten nitride is about 10 to about 60 angstroms thick.

3. The method of claim 1, wherein the liner layer of tungsten is about 30 to about 300 angstroms thick.

4. The method of claim 1, wherein the seed layer of tungsten nitride has a nitrogen concentration of about 18 to about 35 atomic percent.

5. The method of claim 1, further comprising performing a nitrogen radical treatment before filling the feature with the tungsten bulk fill to provide an incubation delay for a subsequent deposition process.

6. The method of claim 1, further comprising depositing a nucleation layer using a mixture of tungsten hexafluoride (WF₆) with silane (SiH4) or diborane (B₂H₆) via an atomic layer deposition (ALD) process after depositing the liner layer of tungsten.

7. The method of claim 1, further comprising performing a planarization process on the substrate after filling the feature with the tungsten bulk fill.

8. The method of claim 1, wherein the substrate consists essentially of silicon oxide.

9. The method of claim 1, wherein a width of the feature is between about 5 and about 65 nanometers.

10. A method of filling a feature in a substrate, comprising:
depositing a seed layer of tungsten nitride in the feature via a physical vapor deposition (PVD) process;
depositing a liner layer of tungsten on the seed layer of tungsten nitride in the feature via a PVD process;
performing a nitrogen radical treatment on the liner layer to provide an incubation delay for a subsequent deposition process; and
subsequently filling the feature with a tungsten bulk fill via a chemical vapor deposition (CVD) process.

11. The method of claim 10, wherein depositing the liner layer of tungsten is performed at a temperature of about 20 to about 350 degrees Celsius.

12. The method of claim 10, wherein the liner layer is thicker than the seed layer.

13. The method of claim 10, wherein the tungsten bulk fill is performed using tungsten hexafluoride (WF₆) and hydrogen (H₂) as precursors.

14. The method of claim 10, further comprising depositing a nucleation layer using a mixture of tungsten hexafluoride (WF₆) with silane (SiH4) or diborane (B₂H₆) via an atomic layer deposition (ALD) process after depositing the liner layer of tungsten and prior to performing the nitrogen radical treatment.

15. The method of claim 10, wherein an aspect ratio of the feature is between about 1:1 and about 15:1.

16. A non-transitory computer readable medium comprising one or more processors, that when executed, perform a method of filling a feature in a substrate, comprising:
depositing a seed layer of tungsten nitride in the feature via a physical vapor deposition (PVD) process;
depositing a liner layer of tungsten on the seed layer of tungsten nitride in the feature via a PVD process; and
subsequently filling the feature with a tungsten bulk fill via a chemical vapor deposition (CVD) process.

17. The computer readable medium of claim 16, wherein the seed layer of tungsten nitride is about 10 to about 60 angstroms thick.

18. The computer readable medium of claim 16, wherein the seed layer of tungsten nitride has a nitrogen concentration of about 18 to about 35 atomic percent.

19. The computer readable medium of claim 16, further comprising performing a nitrogen radical treatment before filling the feature with the tungsten bulk fill to provide an incubation delay for a subsequent deposition process.

20. The computer readable medium of claim 16, further comprising depositing a nucleation layer using a mixture of tungsten hexafluoride (WF₆) with silane (SiH4) or diborane (B₂H₆) via an atomic layer deposition (ALD) process after depositing the liner layer of tungsten.
